(19) United States
(12) Patent Application Publication
(10) Pub. No.: US 2003/0166338 A1
(43) Pub. Date: Sep. 4, 2003

(54) CMP slurry for metal and method for manufacturing metal line contact plug of semiconductor device using the same

(76) Inventors: Ki Cheol Ahn, Kyoungki-do (KR); Pan Ki Kwon, Kyoungki-do (KR); Jong Goo Jung, Kyoungki-do (KR); Sang Ick Lee, Kyoungki-do (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/331,360

(22) Filed: Dec. 30, 2002

(30) Foreign Application Priority Data
Dec. 31, 2001 (KR) 2001-89107
Jun. 24, 2002 (KR) 2002-35430

(51) Int. Cl. H01L 21/302; H01L 21/461

(52) U.S. Cl. 438/689

(57) ABSTRACT

A chemical mechanical polishing (hereinafter, referred to as ‘CMP’) slurry for metal is disclosed, more specifically, method for manufacturing metal line contact plug of semiconductor device using an acidic CMP slurry for oxide film further comprising an oxidizer and a complexing agent, which polishes a metal, an oxide film and a nitride film at a similar speed, thereby easily separates a metal line contact plug.

### BACKGROUND

1. Technical Field

A chemical mechanical polishing (hereinafter, referred to as ‘CMP’) slurry for metal is disclosed, more specifically, method for manufacturing a metal line contact plug of semiconductor device is disclosed that employs an acidic CMP slurry for oxide films further comprising an oxidizer and a complexing agent, which polishes the metal, an oxide film and all a nitride film at a similar speeds, thereby easily separating the metal line contact plug.

2. Description of the Related Art

Generally, highly integrated semiconductor, the integration device can comprise about 8,000,000 transistors per cm₂. Therefore, a multi-layered metal line of high quality which enables such devices to be connected is required for high integration. Such multi-layered metal lines can be embodied by efficiently planarizing dielectrics inserted between adjacent metal lines.

Since a precise process of planarizing the wafer is required, CMP processes have been developed. During a CMP process, materials which need to be removed are chemically eliminated by using chemical materials which have good reactivity in CMP slurries. Simultaneously, the wafer surface is polished mechanically with ultrafine abrasives. The CMP process is performed by injecting liquid slurry between the entire surface of a wafer and a rotating elastic pad.

A conventional slurry used in a CMP process for metal comprises: abrasives such as SiO₂, Al₂O₃ or MnO₂; oxidizers such as H₂O₂, H₅IO₆ or FeNO₃ for oxidizing metal to form oxide films, thereby promoting etching process; small amounts of sulfuric acid, nitric acid or hydrochloric acid for making the slurry acidic; dispersant; complexing agents; and buffers.

When a metal is removed by a CMP process using the conventional slurry, the metal surface is oxidized by the oxidizers, and then the oxidized portion is mechanically polished and removed by abrasives contained in the slurry.

However, since the above-described CMP slurry for metal is expensive thereby increasing the unit cost of the CMP process, the cost of manufacturing the entire device is also increased. As a result, new slurry has been developed which may easily polish metal in small amounts to control costs.

Hereinafter, the conventional method for manufacturing a metal line contact plug of a semiconductor device will be explained with reference to the accompanying drawings.

FIG. 1a is a top plan view after forming a bit line pattern. FIG. 1b is a top plan view after etching a metal line contact plug. FIGS. 2a to 2d illustrate schematically conventional methods for manufacturing metal line contact plugs of semiconductor devices.

Referring FIG. 2a, a diagram illustrating a condition wherein an interlayer insulating film is stacked on an A-A′ cross section of FIG. 1a.

A bit line layer (not shown) and a mask insulating film (not shown) are formed on a semiconductor substrate 11. Then, bit line patterns 13 with mask insulating film patterns 15 stacked thereon are formed on a semiconductor substrate 11 by etching the resultant surface.

Here, the mask insulating film (not shown) is formed using a nitride film with a thickness t₁. Next, an interlayer insulating film 17 is formed on top surface of the resultant structure using an oxide film.

Referring FIG. 2b, a diagram illustrating a B-B′ cross section of FIG. 1b.

An interlayer insulating film pattern 17-1 and a metal line contact hole 19 are formed by etching the interlayer insulating film 17 using the metal line contact mask (not shown) as an etching mask. Here, a region “C” shown in FIG. 1b represents a region wherein the metal line contact hole 19 is formed by etching the interlayer insulating film 17 and a region “D” represents a region wherein the metal line contact hole 19 is not formed.

A predetermined thickness of an oxide film (not shown) on the resultant structure is deposited, and then the oxide film is etched to form a oxide spacers 21 on the sidewalls of the metal line contact hole 19, mask insulating film patterns 15 and bit lines 13. Here, the thickness of the mask insulating film patterns 15 formed in the metal line contact hole 19 is decreased to t₂ due to etching processes to form the metal line contact hole 19 and to form the oxide film spacer 21.

Referring to FIG. 2c, a metal layer 23 is stacked on the resultant structure. Here, the metal layer 23 has step coverage of t₃ in the metal line contact hole 19 and of t₄ from the mask insulating film pattern 15-1.

Referring to FIG. 2d, a metal line contact plug 25 is formed by removing portions of the metal layer 23, the interlayer insulating film 17-1 and the oxide film spacers 21 using a CMP process. Here, in order that the metal line contact plug 25 is separated into P1 and P2 using the CMP process, a depth of t₄ should be polished using a slurry to remove portions of the metal layer 23.

A polishing speed should be similar between films to remove the above multi-layered films. However, a polishing speed of metal layers is over 20 times faster than that of oxide films when a metal is polished using conventional CMP slurry for metal.

As a result, since a metal layer of a low step coverage is not removed easily due to slow polishing speeds of a oxide films or a nitride films, a metal line contact plug is not separated, and polishing process time is increased.

In other words, as shown in 30 of FIG. 3, uniformity in wafers is degraded and an equipment vibration phenomenon is generated, resulting in decreased stability of the process.

Additionally, since the above-described CMP process has a rapid polishing speed in peripheral circuit regions having low pattern density, mask insulating film patterns (not shown) on the bit lines formed on peripheral circuit regions (not shown) are damaged before complete separation of metal line contact plugs to expose bit lines (not shown). As a result, bridges are formed between devices and leakage current is increased, resulting in degradation of reliability and operation characteristics of devices.

In order to overcome the above-described problem, a CMP slurry for polishing multi-layers was used. For example, in the U.S. Pat. No. 6,200,875, method for forming capacitors is disclosed wherein contact plugs are formed by polishing simultaneously silicon films and oxide films using CMP slurry for oxide films. However, the composition of the CMP slurry for oxide films is not described therein.

### SUMMARY OF THE DISCLOSURE

Accordingly, a CMP slurry for metal is disclosed which may easily separate a metal line contact plug by polishing a nitride film, an oxide film and a metal layer, all at a similar speed.

A method for manufacturing a metal line contact plug of a semiconductor device using the above CMP slurry is also disclosed.

### BRIEF DESCRIPTION OF THE DRAWINGS

FIG. 1a is a top plan view after formation of a bit line pattern.

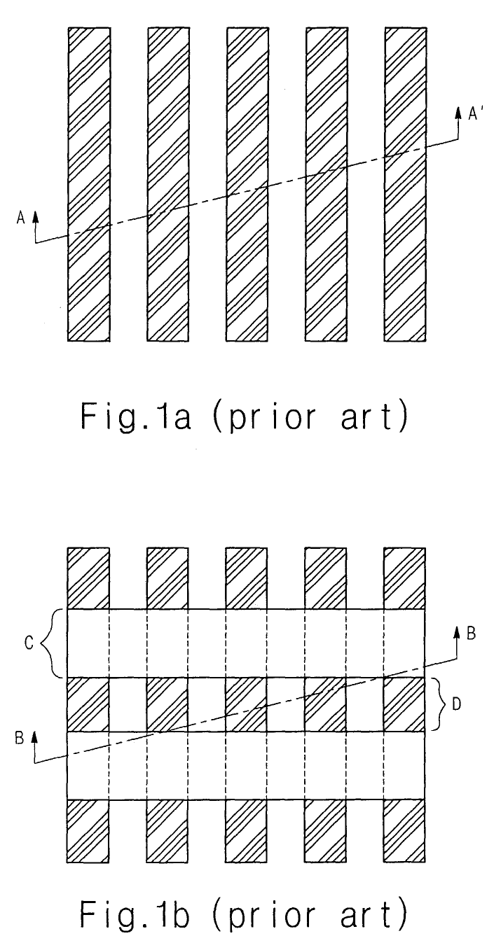

FIG. 1b is a top plan view after etching of a metal line contact plug.

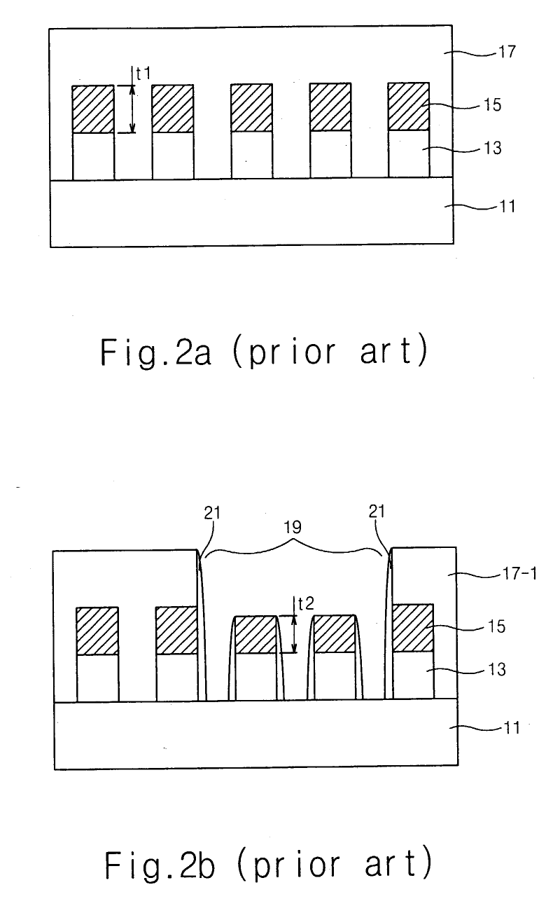

FIGS. 2a through 2d illustrate, schematically, conventional methods of manufacturing metal line contact plugs of semiconductor devices.

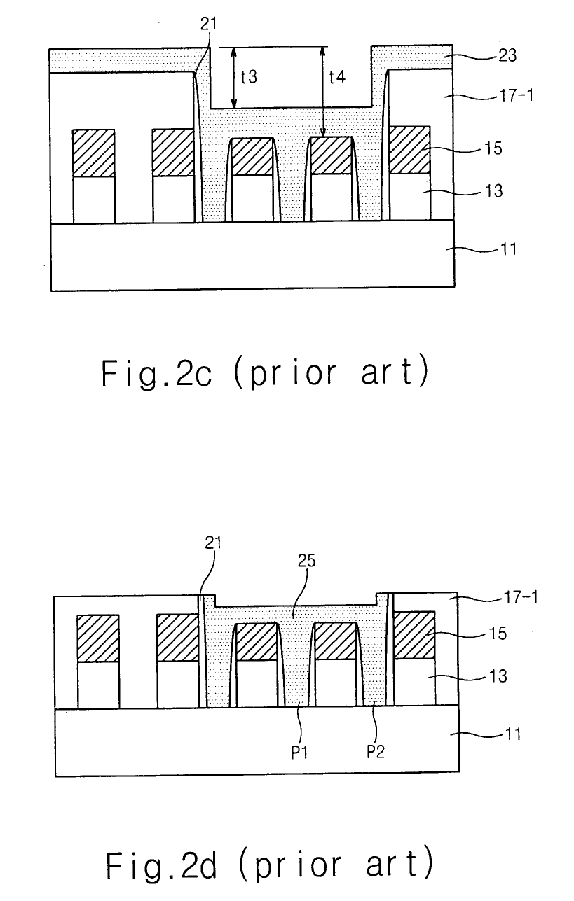

FIG. 3 is a CD SEM photograph of a conventional metal line contact plug.

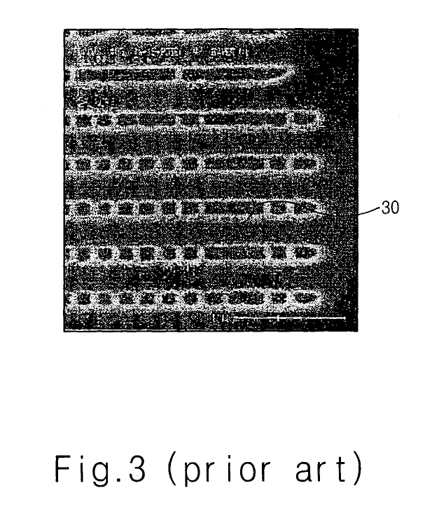

FIG. 4a is a top plan view after formation of a bit line pattern in accordance with this disclosure.

FIG. 4b is a top plan view after etching of a metal line contact plug in accordance with this disclosure.

FIGS. 5a through 5d illustrate, schematically, disclosed methods for manufacturing metal line contact plugs of semiconductor devices in accordance with this disclosure.

FIG. 6 is a CD SEM photograph of a metal line contact plug in accordance with this disclosure;

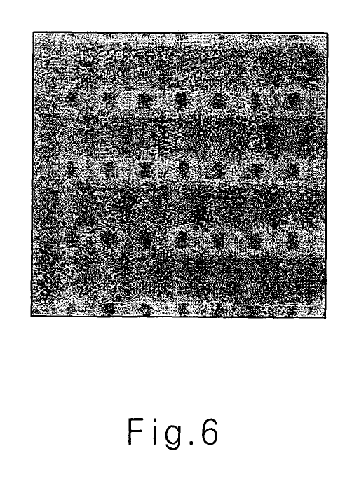

FIG. 7 is a graph illustrating a polishing speed and selectivity when metal, oxide and nitride films are polished in a blanket wafer using the disclosed CMP slurry.

### DETAILED DESCRIPTION OF THE PRESENTLY PREFERRED EMBODIMENTS

A CMP slurry for metal is disclosed which the acidic CMP slurry for oxide film further comprises an oxidizer and a complexing agent and which may easily separate easily a metal line contact plug by polishing a nitride film, an oxide film and a metal layer, all at a similar speed.

It is preferable that a CMP slurry for oxide film having a pH ranging from 2 to 7 comprises an oxidizer and a complexing agent. As a result, the disclosed CMP slurry for metal preferably has a pH ranging from 2 to 3.

The disclosed CMP slurry has a polishing selectivity in the, range of 1:1˜2:1˜3 for a nitride film:oxide film:metal layer. The polishing selectivity is similar.

The oxidizer, which oxidizes metals to increase a polishing speed, is selected from the ground consisting of H₂O₂, H₅IO₆, FeNO₃ and combinations thereof. Here, the oxidizer is present in an amount ranging from 0.5 to 10 vol % and preferably from 2 to 6 vol % based on the CMP slurry.

The complexing agent forms a complexing compound with metal falling apart from the polishing process to prevent re-accretion of polishing by-products.

The complexing agent is selected from the ground consisting of hydrocarbon compounds containing carboxyl group (—COOH) such as tartaric acid, hydrocarbon compounds containing nitro group (—NO₂) such as nitroglycerine, hydrocarbon compounds containing ester group (—COO—) hydrocarbon compounds containing ether group (—O—), hydrocarbon compounds containing amino group (—NH₂) such as ethylenediamine and combinations thereof.

Here, the complexing agent has a molecular weight ranging from 40 to 1000 and is preferably selected from the Formulas 1 to 13:

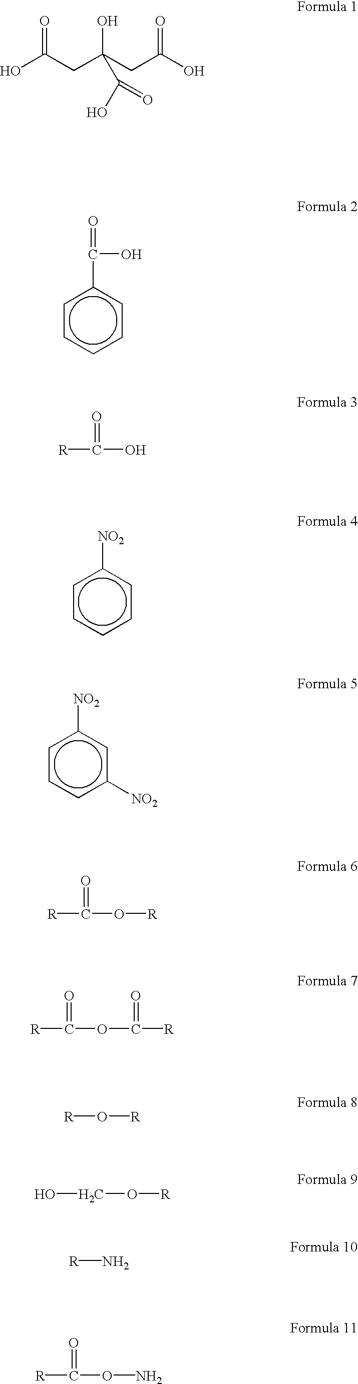

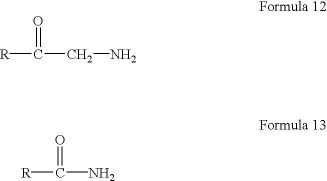

wherein R is a branched or linear substituted C₁-C₅₀ alkyl or aromatic group.

The complexing agent is present in an amount ranging from 0.001 to 5 vol % based on the CMP slurry. When the amount exceeds 0.001 to 5 vol %, chemical etching ability is improved due to increase of chemical factors, thereby resulting in degradation of the CMP process. Accordingly, the complexing agent is added in an amount below 5 vol %, preferably ranging from 0.01 to 1 vol %.

A general complexing agent included in the slurry used in the general metal CMP process forms a complexing compound with metal falling apart from the polishing process to prevent re-accretion of polishing by-products.

The disclosed complexing agent induces an oxide film formed on metal surface due to the oxidizer to be easily polished, and also breaks the bond of metal-oxide film to remove metal. When the acidic slurry used in the CMP process for forming a metal line contact plug does not contain an oxidizer or a complexing agent or contains one of them, the polishing speed of metal does not vary. However, when the acidic slurry contains both an oxidizer and a complexing agent mixed at a proper proportion, the polishing speed of the metal can be increased considerably.

The CMP slurry comprises an abrasive selected from the group consisting of SiO₂, CeO₂, ZrO₂, Al₂O₃ and combinations thereof. Here, the slurry comprises an abrasive in an amount ranging from 0.5 to 30 wt % and preferably from 10 to 30 wt % based on the CMP slurry.

The CMP slurry comprises an abrasive of 0.5 to 30 wt % based on the CMP slurry, an H₂O₂ as oxidizer in a volume ratio in the range of 3˜4:1 in abrasive oxidizer, and a complexing agent in a volume ratio in the range of 20˜50:1 in oxidizer:complexing agent, and then to obtain the CMP slurry for metal having a polishing selectivity in the range of 1:1˜2:1˜3 in a nitride film:oxide film:metal structure.

The disclosed CMP slurry for metal may further comprise dispersants and buffers.

There is also provided method for manufacturing metal line contact plug of semiconductor device, the method comprising:

forming a stack pattern of bit line and a mask insulating film pattern on a semiconductor substrate;

forming an interlayer insulating film on the entire surface of the resultant structure;

selectively etching away the interlayer insulating film to form a metal line contact hole;

forming an oxide film spacer on sidewalls of the metal line contact hole and stack patterns of the bit line and mask insulating film in the metal line contact hole;

depositing a metal layer on the entire surface of the resultant structure; and

performing a CMP process using a disclosed slurry to form a metal line contact plug.

The mask insulating film is a nitride film and the interlayer insulating film is an oxide film.

The metal layer is selected form the group consisting of TiN, W, Al layers alloy thereof, and combinations thereof.

The disclosed CMP slurry and the disclosed manufacturing method will be described in detail with reference to the accompanying drawings.

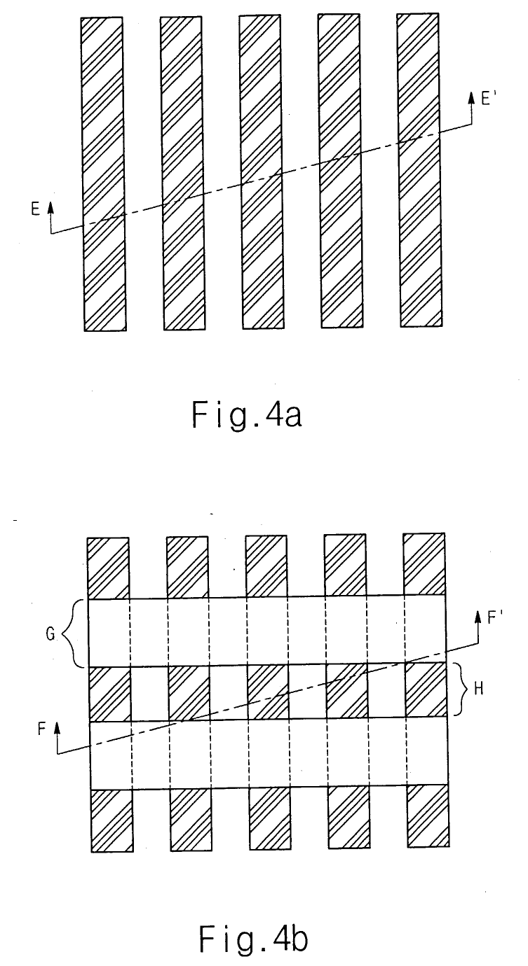

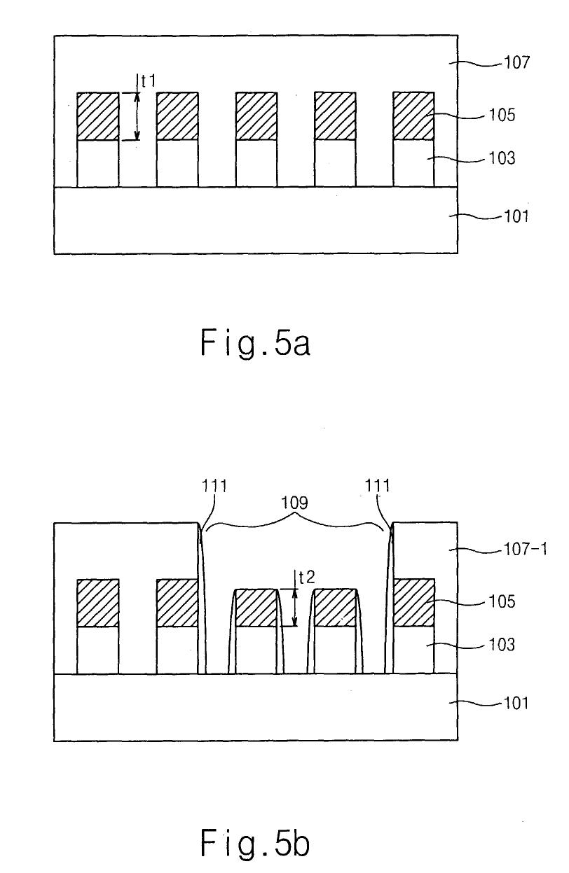

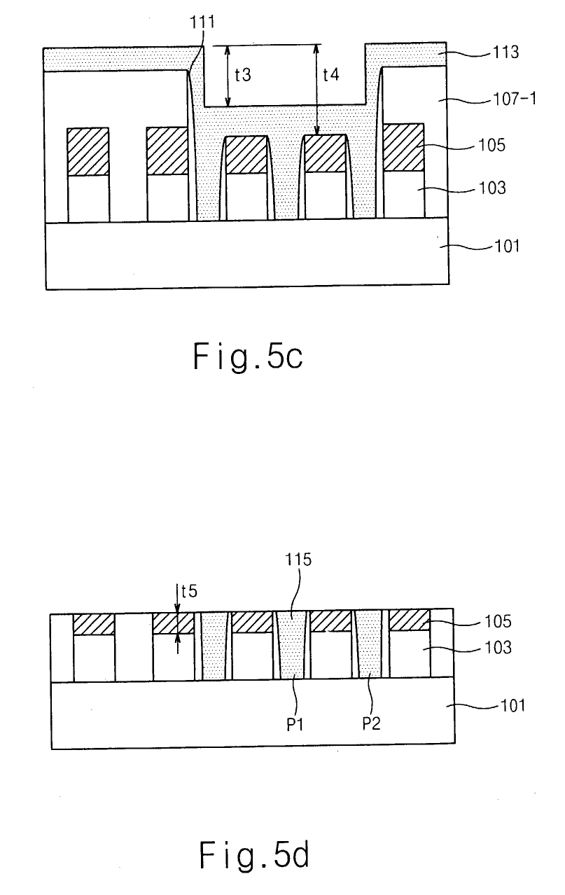

FIG. 4a is a top plan view after forming a bit line pattern. FIG. 4b is a top plan view after etching a metal line contact plug. FIGS. 5a through 5d illustrate methods for manufacturing metal line contact plugs of semiconductor devices using the acidic CMP slurries disclosed herein.

Referring FIG. 5a, a diagram illustrating a condition wherein an interlayer insulating film is stacked on an E-E′ cross section of FIG. 4a.

A bit line layer (not shown), which a diffusion barrier film (not shown) and a metal layer (not shown) are sequentially formed, and a mask insulating film (not shown) are formed on a semiconductor substrate 101.

Thereafter, the resultant structure is etched to form the bit line patterns 103 on which the mask insulating patterns 105 are stacked.

Here, the diffusion barrier film (not shown) is formed of Ti/TiN by a chemical vapor deposition (CVD) process using TiCl₄ as a source. The metal layer (not shown) is formed of tungsten.

The mask insulating film (not shown) is formed of a nitride film at a temperature ranging from 500 to 600° C. by a plasma chemical deposition process, and at its thickness of t₁.

Next, an interlayer insulating film 107 is formed on top surface of the resultant structure using an oxide film.

Referring FIG. 5b, illustrates a F-F′ cross section of FIG. 4b. An interlayer insulating film pattern 107-1 and a metal line contact hole 109 are formed by etching the interlayer insulating film 107 using a metal line contact mask (not shown) as an etching mask.

Here, a region “G” shown in FIG. 4b represents a region wherein the metal line contact hole 109 is formed by etching the interlayer insulating film 107 and a region “H” represents a region where the metal line contact hole 109 is not formed.

Next, a predetermined thickness of oxide film (not shown) is formed on the resultant structure, and then an oxide film spacer 111 is formed at sidewalls of the metal line contact hole 109, the bit line pattern 103 and the mask insulating film pattern 105 by etching depositing top surface it.

Here, the thickness of the mask insulating film pattern 105 in the metal line contact hole 109 is decreased to t₂ due to the etching processes to form the metal line contact hole 109 and to form the oxide film spacer 111.

Referring to FIG. 5c, a metal layer 113 is deposited on the resultant surface. Here, the metal layer 113 consisting of TiN is deposited using an atomic layer deposition (ALD) process has step coverage of t₃ in the metal line contact hole 109 and of t₄ from the mask insulating pattern 105.

Since TiN has excellent activity, it can be easily polished by the disclosed slurry. The disclosed slurry can be used during polishing process of a metal line using W or Al in addition to TiN.

Referring to 5d, a CMP process is performed on the metal layer 113, the interlayer insulating film 107-1, the oxide film spacer and the predetermined thickness of the mask insulating film patterns 105, using a disclosed CMP slurry for metal. As a result, a uniform metal line contact plug 115 is formed in which a region P₁ and a region P₂ are completely separated.

Since the metal layer 113, the interlayer insulating film pattern 107-1, the oxide film spacer 111 and the mask insulating film pattern 105 are sequentially polished at a thickness of more than t₄ using the CMP process, a thickness of the mask insulating film patterns 105 on the bit lines 103 decrease to t₅ smaller than t₂.

The entire surface etching process using a dry etching method can be performed the metal layer 113 when the interlayer insulating pattern 107-1 is exposed. Therefore, the deposition thickness ranging from 80 to 90% of the metal layer is then removed.

The disclosed CMP slurry can be used to perform a CMP process on an oxide film, and has also an excellent effect on polishing a metal layer with good activity. In other words, if a CMP process is performed using a disclosed CMP slurry as described above, it is possible to prevent the phenomenon that a metal line contact plug is not sufficiently separated because a metal layer having a portion with a low step coverage is not sufficiently removed, thereby minimizing dependency on CMP equipment, easily performing the subsequent process by planarization and improving insulating characteristics between metal line contact plugs.

The disclosed acidic CMP slurry for oxide film further comprising an oxidizer and a complexing agent to measure a polishing speed of polishing a nitride film, an oxide film and a metal layer on a blanket wafer will be described in more detail by referring to examples below, which are not intended to be limiting.

### COMPARATIVE EXAMPLE

A high density plasma (HDP) oxide film, a SiN film and a TiN film were polished on a blanket wafer by CMP equipment under a head pressure of 3 psi and a belt speed of 700 fpm using a CMP slurry for oxide film with a pH of 3 including SiO₂ present at 30 wt % as an abrasive. Then, each of the measured polishing speed was shown in Table 1.

### Example 1

H₂O₂ as oxidizer was added in a CMP slurry for oxide film with a pH of 3 including 30 w % SiO₂ as an abrasive to have a weight ratio in the range of 4:1 in abrasive:oxidizer. Then, a compound of Formula 1 as complexing agent was added in the CMP slurry to have a weight ratio in the range of 40:1 in oxidizer:complexing agent, thereby obtaining a CMP slurry for metal.

A HDP oxide film, a SiN film and a TiN film were polished on a blanket wafer by CMP equipment under a head pressure of 3 psi and a belt speed of 700 fpm using the CMP slurry for metal manufactured above. Then, each of the measured polishing speed was shown in Table 1.

### Example 2

H₂O₂ as oxidizer was added in a CMP slurry for oxide film with a pH of 3 including 30 w % SiO₂ as an abrasive to have a weight ratio in the range of 3:1 in abrasive:oxidizer, and then deionized water having the same weight of the oxidizer was added. Next, a compound of Formula 1 as complexing agent was added in the CMP slurry to have a weight ratio in the range of 40:1 in oxidizer:complexing agent, thereby obtaining a CMP slurry for metal.

The procedure of Example 1 was repeated using the CMP slurry manufactured above. Then, each of the measured polishing speed was shown in Table 1.

### Example 3

H₂O₂ as oxidizer was added in a CMP slurry for oxide film with a pH of 3 including 30 w % SiO₂ as an abrasive to have a weight ratio in the range of 4:1 in abrasive:oxidizer. Then, a compound of Formula 1 as complexing agent was added in the CMP slurry to have a weight ratio in the range of 40:1 in oxidizer:complexing agent, thereby obtaining a CMP slurry for metal.

A HDP oxide film, a SiN film and a TiN film were polished on a blanket wafer by CMP equipment under a head pressure of 5 psi and a belt speed of 700 fpm using the CMP slurry for metal manufactured above. Then, each of the measured polishing speed was shown in Table 1.

### Example 4

H₂O₂ as oxidizer was added in a CMP slurry for oxide film with a pH of 3 including 30 w % SiO₂ as an abrasive to have a weight ratio in the range of 4:1 in abrasive:oxidizer. Then, a compound of Formula 1 as complexing agent was added in the CMP slurry to have a weight ratio in the range of 40:1 in oxidizer:complexing agent, thereby obtaining a CMP slurry for metal.

A HDP oxide film, a SiN film and a TiN film were polished on a blanket wafer by CMP equipment under a head pressure of 6 psi and a belt speed of 700 fpm using the CMP slurry for metal manufactured above. Then, each of the measured polishing speed was shown in Table 1.

TABLE 1

Polishing speed (unit: Å/min)

| | Nitride film (SiN) | HDP oxide film | Metal (TiN) |
|---|---|---|---|
| Comparative | 1917 | 2994 | 625 |
| Example | | | |
| Example 1 | 1800 | 2432 | 4000 |
| Example 2 | 1291 | 1816 | 3261 |
| Example 3 | 2524 | 3525 | 3261 |
| Example 4 | 2685 | 4052 | 3352 |

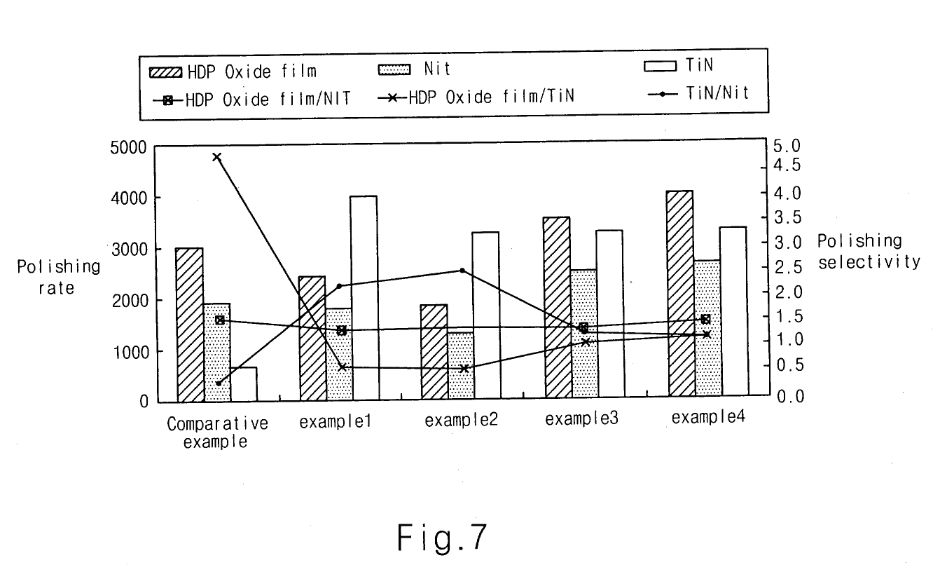

The graph of FIG. 7 illustrates a polishing selectivity of oxide film/nitride film, oxide film/metal and metal/nitride film calculated using the polishing speed measured in the examples. As a result, it is shown that oxide film, nitride film and metal all have similar polishing selectivity when the disclosed slurry for oxide films further comprising an oxidizer and a complexing agent is sued than when a slurry for oxide films which does not contain an oxidizer and a complexing agent is used.

As discussed earlier, a metal line contact plug can be easily separated by a CMP process using an acidic CMP slurry for oxide film further comprising an oxidizer and a complexing agent which polishes a nitride film, an oxide film and a metal, all at a similar speed.

Additionally, conventional CMP slurry for metal is ten times more expensive than conventional CMP slurry for oxide film. As a result, if a CMP is performed on a metal using the disclosed CMP slurry for oxide film of the present invention, the cost of the process is reduced and dependency on CMP equipment is minimized. Also, because regions of metal line contact plugs are completely separated, insulating characteristics between metal line contact plugs for easily performing the subsequent process are improved.

What is claimed is:

1. A chemical mechanical polishing (CMP) slurry for oxide films having a pH ranging from 2 to 7, and comprising an oxidizer and a complexing agent.

2. The CMP slurry according to claim 1, wherein the CMP slurry has a pH ranging from 2 to 3.

3. The CMP slurry according to claim 1, wherein the CMP slurry has a polishing selectivity in the range of 1:1˜2:1˜3 for a nitride film:oxide film:metal layer.

4. The CMP slurry according to claim 1, wherein the oxidizer is selected from the ground consisting of H₂O₂, H₅IO₆, FeNO₃ and combinations thereof.

5. The CMP slurry according to claim 1, wherein the oxidizer is present in an amount ranging from 0.5 to 10 vol % based on the CMP slurry.

6. The CMP slurry according to claim 1, wherein the oxidizer is present in an amount ranging from 2 to 6 vol % based on the CMP slurry.

7. The CMP slurry according to claim 1, wherein the completing agent is selected from the group consisting of hydrocarbon compounds containing carboxyl group (—COOH), hydrocarbon compounds containing nitro group (—NO₂) hydrocarbon compounds containing ester group (—COO—), hydrocarbon compounds containing ether group (—O—), hydrocarbon compounds containing amino group (—NH₂) and combinations thereof.

8. The CMP slurry according to claim 7, wherein the complexing agent is selected from the group consisting of the Formulas 1 to 13: 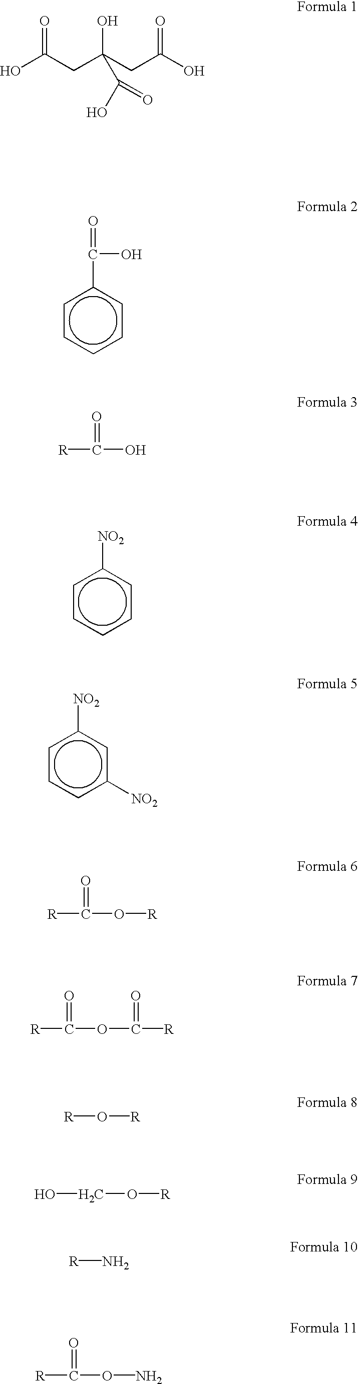 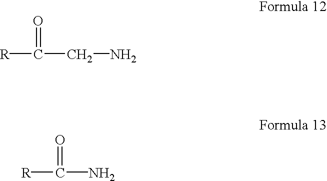
wherein R is a branched or linear substituted C₁-C₅₀ alkyl or aromatic group.

9. The CMP slurry according to claim 7, wherein the complexing agent has a molecular weight ranging from 40 to 1000.

10. The CMP slurry according to claim 1, wherein the complexing agent is present in an amount ranging from 0.001 to 5 vol % based on the CMP slurry.

11. The CMP slurry according to claim 10, wherein the complexing agent is present in an amount ranging from 0.01 to 1 vol % based on the CMP slurry.

12. The CMP slurry according to claim 1, wherein the slurry comprises an abrasive selected from the group consisting of SiO₂, CeO₂, ZrO₂, Al₂O₃ and combinations thereof.

13. The CMP slurry according to claim 1, wherein the slurry comprises an abrasive in an amount ranging from 0.5 to 30 wt % in the CMP slurry.

14. The CMP slurry according to claim 1, wherein the slurry comprises an abrasive in an amount ranging from 10 to 30 wt % in the CMP slurry.

15. The CMP slurry according to claim 1, wherein the CMP slurry comprises an abrasive in an amount ranging form 0.5 to 30 wt % based on the CMP slurry; an oxidizer in a volume ratio in the range of 3˜4:1 in abrasive:oxidizer; and a complexing agent of the following Formula 1 in a volume ratio in the range of 20˜50:1 in oxidizer:complexing agent:

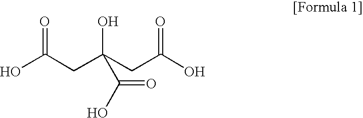

16. The CMP slurry according to claim 15, wherein the abrasive is SiO₂ and the oxidizer is H₂O₂.

17. A method for manufacturing metal line contact plug of semiconductor device comprising a CMP process using the CMP slurry of claim 1.

18. A method for manufacturing a metal line contact plug of a semiconductor device, comprising:
forming a stack pattern of bit line and a mask insulating film pattern on a semiconductor substrate;
forming an interlayer insulating film on the entire surface of the resultant structure;
selectively etching away the interlayer insulating film to form a metal line contact hole;
forming an oxide film spacer on sidewalls of the metal line contact hole and stack patterns of the bit line and mask insulating film in the metal line contact hole;
depositing a metal layer on the entire surface of the resultant structure; and
performing a CMP process using a slurry of claim 1 to form a metal line contact plug.

19. The method according to claim 18, wherein the mask insulating film is a nitride film.

20. The method according to claim 18, wherein the interlayer insulating film is an oxide film.

21. The method according to claim 18, wherein the metal layer is selected form the group consisting of TiN, W, Al, alloy thereof, and combination thereof.
